(19) United States
(12) Patent Application Publication
(10) Pub. No.: US 2012/0070572 A1
(43) Pub. Date: Mar. 22, 2012

(54) Vapor Delivery System For Use in Imprint Lithography

(75) Inventors: Zhengmao Ye, Austin, TX (US); Rick Ramos, El Paso, TX (US); Edward Brian Fletcher, Austin, TX (US); Christopher Ellis Jones, Austin, TX (US); Dwayne L. LaBrake, Cedar Park, TX (US)

(73) Assignee: MOLECULAR IMPRINTS, INC., Austin, TX (US)

(21) Appl. No.: 13/228,298

(22) Filed: Sep. 8, 2011

Related U.S. Application Data
(60) Provisional application No. 61/380,760, filed on Sep. 8, 2010.

(51) Int. Cl. B05D 5/10; C23C 16/448

(52) U.S. Cl. 427/207.1; 118/715

(57) ABSTRACT

Described are systems and method of using a vapor delivery system for enabling delivery of an adhesion promoter material during an imprint lithography process.

### CROSS-REFERENCE TO RELATED APPLICATION

This application claims priority to U.S. application Ser. No. 61/380,760 filed Sep. 8, 2010, which is incorporated by reference herein in its entirety.

### BACKGROUND

Nano-fabrication includes the fabrication of very small structures that have features on the order of 100 nanometers or smaller. One application in which nano-fabrication has had a sizeable impact is in the processing of integrated circuits. The semiconductor processing industry continues to strive for larger production yields while increasing the circuits per unit area formed on a substrate, therefore nano-fabrication becomes increasingly important. Nano-fabrication provides greater process control while allowing continued reduction of the minimum feature dimensions of the structures formed. Other areas of development in which nano-fabrication has been employed include biotechnology, optical technology, mechanical systems, and the like.

An exemplary nano-fabrication technique in use today is commonly referred to as imprint lithography. Exemplary imprint lithography processes are described in detail in numerous publications, such as U.S. Patent Publication No. 2004/0065976, U.S. Patent Publication No. 2004/0065252, and U.S. Pat. No. 6,936,194, all of which are hereby incorporated by reference herein.

An imprint lithography technique disclosed in each of the aforementioned U.S. patent publications and patent includes formation of a relief pattern in a formable (polymerizable) layer and transferring a pattern corresponding to the relief pattern into an underlying substrate. The substrate may be coupled to a motion stage to obtain a desired positioning to facilitate the patterning process. The patterning process uses a template spaced apart from the substrate and a formable liquid applied between the template and the substrate. The formable liquid is solidified to form a rigid layer that has a pattern conforming to a shape of the surface of the template that contacts the formable liquid. After solidification, the template is separated from the rigid layer such that the template and the substrate are spaced apart. The substrate and the solidified layer are then subjected to additional processes to transfer a relief image into the substrate that corresponds to the pattern in the solidified layer.

### BRIEF DESCRIPTION OF DRAWINGS

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention, and are therefore not to be considered limiting of its scope, for the invention may admit to other equally effective embodiments.

FIG. 1 illustrates a simplified side view of a lithographic system.

FIG. 2 illustrates a simplified side view of the substrate illustrated in FIG. 1, having a patterned layer thereon.

FIG. 3 illustrates an exemplary embodiment of a vapor delivery system having a single reservoir and a single vaporizer coil system.

FIG. 4 illustrates an exemplary embodiment of a vapor delivery system having a single reservoir and a multi-vaporizer coil system.

FIG. 5 illustrates an exemplary embodiment of a vapor delivery system having multiple reservoirs and a single vaporizer coil system.

FIG. 6 illustrates an exemplary embodiment of a vapor delivery system having multiple reservoirs and a multi-vaporizer coil system.

FIG. 7 illustrates an exemplary embodiment of a vapor delivery system having a single reservoir and a gas line providing a carrier gas for transport of a fluid.

### DETAILED DESCRIPTION

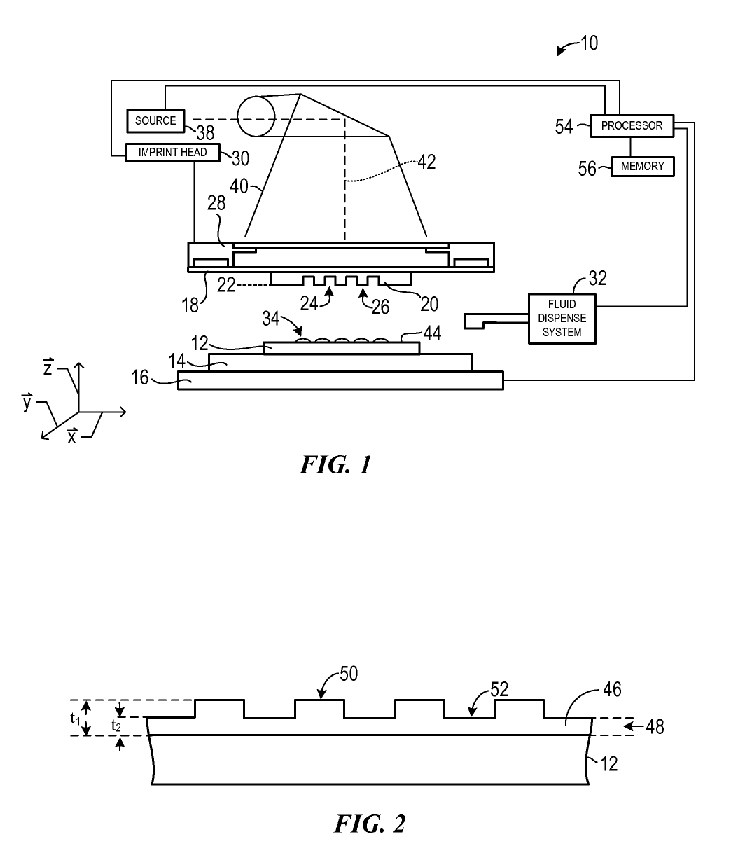

Referring to the figures, and particularly to FIG. 1, illustrated therein is a lithographic system 10 used to form a relief pattern on substrate 12. Substrate 12 may be coupled to substrate chuck 14. As illustrated, substrate chuck 14 is a vacuum chuck. Substrate chuck 14, however, may be any chuck including, but not limited to, vacuum, pin-type, groove-type, electrostatic, electromagnetic, and/or the like. Exemplary chucks are described in U.S. Pat. No. 6,873,087, which is hereby incorporated by reference herein.

Substrate 12 and substrate chuck 14 may be further supported by stage 16. Stage 16 may provide translational and/or rotational motion along the x, y, and z-axes. Stage 16, substrate 12, and substrate chuck 14 may also be positioned on a base (not shown).

Spaced-apart from substrate 12 is template 18. Template 18 may include a body having a first side and a second side with one side having a mesa 20 extending therefrom towards substrate 12. Mesa 20 having a patterning surface 22 thereon. Further, mesa 20 may be referred to as mold 20. Alternatively, template 18 may be formed without mesa 20.

Template 18 and/or mold 20 may be formed from such materials including, but not limited to, fused-silica, quartz, silicon, organic polymers, siloxane polymers, borosilicate glass, fluorocarbon polymers, metal, hardened sapphire, and/or the like. As illustrated, patterning surface 22 comprises features defined by a plurality of spaced-apart recesses 24 and/or protrusions 26, though embodiments of the present invention are not limited to such configurations (e.g., planar surface). Patterning surface 22 may define any original pattern that forms the basis of a pattern to be formed on substrate 12.

Template 18 may be coupled to chuck 28. Chuck 28 may be configured as, but not limited to, vacuum, pin-type, groove-type, electrostatic, electromagnetic, and/or other similar chuck types. Exemplary chucks are further described in U.S. Pat. No. 6,873,087, which is hereby incorporated by reference herein. Further, chuck 28 may be coupled to imprint head 30 such that chuck 28 and/or imprint head 30 may be configured to facilitate movement of template 18.

System 10 may further comprise a fluid dispense system 32. Fluid dispense system 32 may be used to deposit formable material 34 (e.g., polymerizable material) on substrate 12. Formable material 34 may be positioned upon substrate 12 using techniques, such as, drop dispense, spin-coating, dip coating, chemical vapor deposition (CVD), physical vapor deposition (PVD), thin film deposition, thick film deposition, and/or the like. Formable material 34 may be disposed upon substrate 12 before and/or after a desired volume is defined between mold 22 and substrate 12 depending on design considerations. Formable material 34 may be functional nano-particles having use within the bio-domain, solar cell industry, battery industry, and/or other industries requiring a functional nano-particle. For example, formable material 34 may comprise a monomer mixture as described in U.S. Pat. No. 7,157,036 and U.S. Patent Publication No. 2005/0187339, both of which are herein incorporated by reference. Alternatively, formable material 34 may include, but is not limited to, biomaterials (e.g., PEG), solar cell materials (e.g., N-type, P-type materials), and/or the like.

Referring to FIGS. 1 and 2, system 10 may further comprise energy source 38 coupled to direct energy 40 along path 42. Imprint head 30 and stage 16 may be configured to position template 18 and substrate 12 in superimposition with path 42. System 10 may be regulated by processor 54 in communication with stage 16, imprint head 30, fluid dispense system 32, and/or source 38, and may operate on a computer readable program stored in memory 56.

Either imprint head 30, stage 16, or both vary a distance between mold 20 and substrate 12 to define a desired volume therebetween that is filled by formable material 34. For example, imprint head 30 may apply a force to template 18 such that mold 20 contacts formable material 34. After the desired volume is filled with formable material 34, source 38 produces energy 40, e.g., ultraviolet radiation, causing formable material 34 to solidify and/or cross-link conforming to a shape of surface 44 of substrate 12 and patterning surface 22, defining patterned layer 46 on substrate 12. Patterned layer 46 may comprise a residual layer 48 and a plurality of features shown as protrusions 50 and recessions 52, with protrusions 50 having a thickness t₁ and residual layer having a thickness t₂.

The above-mentioned system and process may be further employed in imprint lithography processes and systems referred to in U.S. Pat. No. 6,932,934, U.S. Pat. No. 7,077,992, U.S. Pat. No. 7,179,396, and U.S. Pat. No. 7,396,475, all of which are hereby incorporated by reference in their entirety.

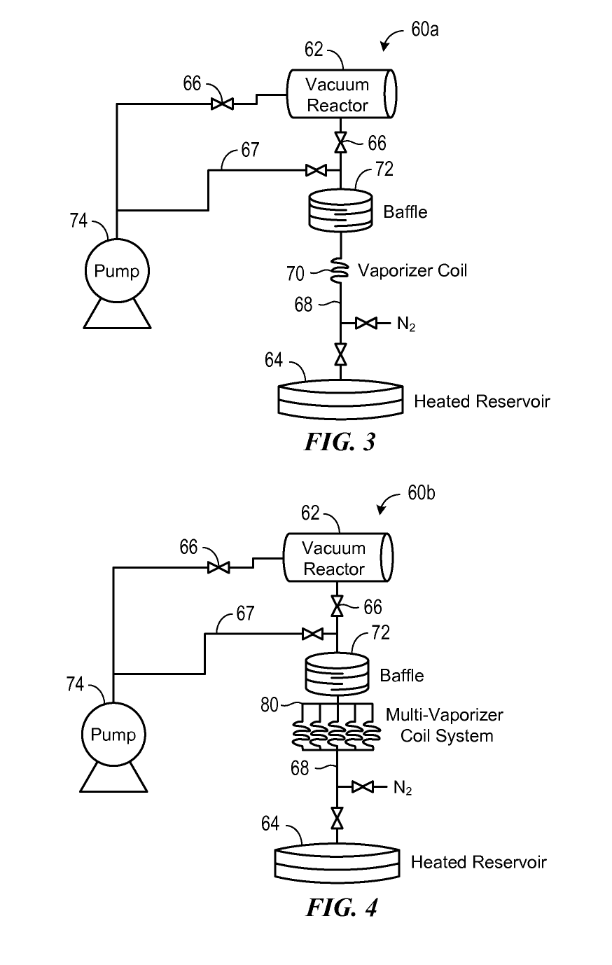

A liquid pre-cursor adhesion promoter may be deposited in a vapor state to substrate 12 to enable the methods described in relation to FIGS. 1 and 2. For example, ValMat®, (Molecular Imprints, Inc, Austin, Tex., USA) is a liquid pre-cursor adhesion promoter. Valmat® comprises a silane compound having a functional group capable of covalently bonding to a polymerizable material typically used in an imprint lithography process, a linker group (such as —CH₂—), and an Si atom with hydrolizable leaving groups. Acryloxymethyltrimethoxysilane is an example of such a compound. Such compounds are described in detail in US 2007/0212494 A1, incorporated herein in its entirety by reference. These compounds are highly reactive and therefore useful as adhesion promoters, but as a result can have limited shelf life and/or stability, particularly when exposed to moisture and/or heat. For example, the viscosity of Valmat® almost doubles after two weeks at 45° C., indicative of changes to its material properties. As such, the vapor delivery system provided herein enables vapor delivery of an adhesion promoter or adhesive material such as ValMat® to substrate 12. Although systems 60a-60d (FIGS. 3-7) are described herein for use with ValMat®, it should be noted that other adhesion promoters and/or materials may be delivered separately or in conjunction with ValMat® using vapor delivery systems 60a-60d. Reference herein to ValMat® shall be understood to generally refer to the compounds as described above and disclosed in US 2007/0212494 A1. Further, while the systems and methods are described below in reference to ValMat®, such reference is intended to be exemplary, and it shall be understood that the systems and methods as described can be used with other like adhesive materials and/or adhesion promoters.

To achieve good coating performance and be used for the production for the substrate coating, the delivery system needs to meet several requirements. First, the ValMat® in the liquid form needs be to fully vaporized (i.e. a finely dispersed gas of ValMat® at the molecular level and not clusters or mists of ValMat® molecules) so that a single monolayer of cross-linked ValMat® can be formed on the substrate. Where ValMat® exists as mist or clusters of ValMat® vapor, it greatly increases the possibility forming a thicker substrate coating region with poor ValMat® cross-linking and lead to adhesion issues. Second, the reactor chamber fill time need to be less than several minutes to minimize the overall process time to meet the throughput requirement, especially for hard disk drive manufacture, which requires more than one thousand disk coating per hour per tool. Third, the delivery/reservoir system should have easy re-fill capability and low delivery system maintenance requirement.

FIGS. 3-7 illustrate exemplary embodiments of vapor delivery systems 60a-60d for enabling delivery of the adhesion promoter. In particular, vapor delivery systems 60a-60d enable delivery of fully vaporized adhesive material (e.g., ValMat®® or similar materials). An exemplary delivery system according to this design includes, (1) a reservoir, in which the ValMat® is kept in the liquid form at temperature ranging from room temperature to 90° C., (2) a vaporizer that may consist of a heated reservoir, a coil vaporizer and a baffler to fully vaporize the ValMat® and store the vaporized ValMat® before releasing them into the reactor chamber, and (3) a nitrogen purge line to purge the vaporizer line and remove residual ValMat® vapor before any maintenance work, which is important due to the highly reactive nature of ValMat® and like materials.

Generally, vapor delivery systems 60a-60d may be a single vacuum environment that includes a reactor 62 and reservoir 64 connected but isolated by delivery line 68 and valves 66. In one embodiment, valves 66 may be pneumatic valves capable of providing fluid to enter reactor 62.

Reservoir 64 and the vacuum chamber or reactor 62 may be held at a pressure below vapor pressure of the fluid to be delivered (e.g., ValMat®). Providing reservoir 64 and vacuum chamber at a pressure below the vapor pressure of the fluid may provide the fluid to exit reservoir 64 in a liquid/vapor state and enter reactor 62 in a vapor state. For example, pressure of reservoir 64 may be set initially at less than approximately 70 mTor. The vapor pressure of ValMat® can range from a few to 26 Torr depending on vaporizer temperature. Delivery line 68 and valves 66 in contact with the fluid may be held at a high temperature. For example, delivery line 68 and valves 66 may be held at a temperature of approximately 90° C. By utilizing this configuration, the ValMat® vapor can be released from the liquid ValMat® in reservoir 64, fully vaporized in the one or more vaporizers (70 or 80), and injected into the reactive chamber 62 which is held at sub-Torr pressure. In addition to achieving full vaporization of ValMat® vapor in this system, vapor condensation or recondensation may be substantially prevented.

Heat may be applied to walls of reservoir 64 to increase the rate of vaporization and maintain the highly dispersed gas to therefore supply more ValMat® vapor to the vaporizer, reduce the ValMat® vapor injection time to the reactive chamber, and increase the throughput. For example, heat may be applied such that vapor pressure of fluid may be increased at a rate at which it evaporates. If heated above 40° C., vapor pressure may nearly double the vapor pressure as compared to a room temperature of 20° C. An inline coil vaporizer 70, baffle 72, N₂ purge, and vacuum purge may also be contained on delivery line 68. Vaporizer 70, baffle 72, as well as reactor 62 itself can also be heated to increase the rate of vaporization.

In one embodiment, vaporizer 70 may be a small diameter coiled tube or tube(s) (e.g., approximately 0.055″ to 0.18″ for the inner diameter). For example, vaporizer 70 may be a small diameter coiled stainless steel tube. Generally, vaporizers in vapor delivery systems are direct injection vaporizers. Such direct injection vaporizers however are unsuitable for use with ValMat® and like compounds due to the high reactivity of the compounds which tends to clog the direct injection nozzles. Here, vaporizer 70 may provide high efficiency liquid vaporization due to the fact that the ValMat® vapor mist will have more chance to vaporize while travelling through the coil in comparison to such direct injection vaporizers, and the high efficiency of vaporization has be confirmed through demonstration of by substrate coating uniformity. One tradeoff of such design is the potential restriction of the vapor flow rate and result in a long process time. A multi-vaporizer coil system 80 may be used to compensate for the flow rate reduction.

In one embodiment, baffle 72 may be positioned in direct line of delivery line 68. Positioning baffle 72 in direct line may provide for additional vaporization efficiency and/or vapor storage volume prior to fluid entering reactor 62. In other words, baffle 72 can both act to both extend the exposure of the liquid to vaporizing conditions, leading to better and more uniform vaporization, as well as act as an additional reservoir or storage of vaporized material. In the latter capacity, this is advantageous for minimizing fill time of reactor chamber 62.

An N₂ purge line may be in direct line on delivery line 68 as well. With N₂ purge line in direct line, vapor may be substantially evacuated from delivery line 68 when systems 60a-60d are idle or prior to the maintenance work. As such, clogging may be prevented in delivery line 68.

In one embodiment, a vacuum bypass line 67 may be positioned in direct line on delivery line 68. Vacuum bypass line 67 may provide for evacuation of fluid and N₂ without having to flow through reactor 62, which minimize potential particle or contamination entering the reactive chamber during the tool bring-up after the system maintenance.

FIG. 3 illustrates an exemplary embodiment of vapor delivery system 60a. Vapor delivery system 60a includes a single reservoir 64 and a single vaporizer 70. Single vaporizer 70 may be selected based on desired vapor flowrate of system 60a. Vaporizer 70 may add flow resistance to delivery line 68. With an increased resistance, vaporization efficiency may be increased, as vapor will be retained in vaporizer 70 longer, leading to better and more uniform vaporization of the material.

FIG. 4 illustrates an exemplary embodiment of vapor delivery system 60b. Vapor delivery system 60b includes a single reservoir 64 and a multiple vaporizer system 80. Vapor delivery system 60b may be similar in design to vapor delivery system 60a. The addition of a multiple vaporizer system 80 may increase overall vapor delivery rate and enhance the throughput in system 60b.

As previously mentioned, existing direct liquid injection vaporizers experience reliability problems when used with ValMat®® due to high reactivity of the material and its tendency to convert to a gel state in the presence of heat and/or moisture. To meet the reactor chamber fill time requirement, the reservoir which stores the liquid ValMat® needs to be kept at an elevated temperature, e.g. 90° C., due to the fact that the vapor pressure of ValMat® increases with the increase in the temperature. For example, the ValMat® vapor pressure is four times higher at 90° C. than room temperature. Higher temperature also increases the ValMat® evaporation rate therefore reducing the time required to accumulate sufficient ValMat® vapor in the reactor chamber to complete the coating process. However, studies indicate a 120% increase in the viscosity of the ValMat® liquid after 2 week of use of the reservoir that is kept at 45° C., which will reduce the evaporation rate and may stop ValMat® supply once the liquid ValMat® liquid completely solidifies. FTIR studies also confirm the change of the characteristics of ValMat®. In addition, clogging of the connector between the vaporizer and the reservoir was also observed which may due the reaction between ValMat® and residual moisture in the delivery system at elevated temperature.

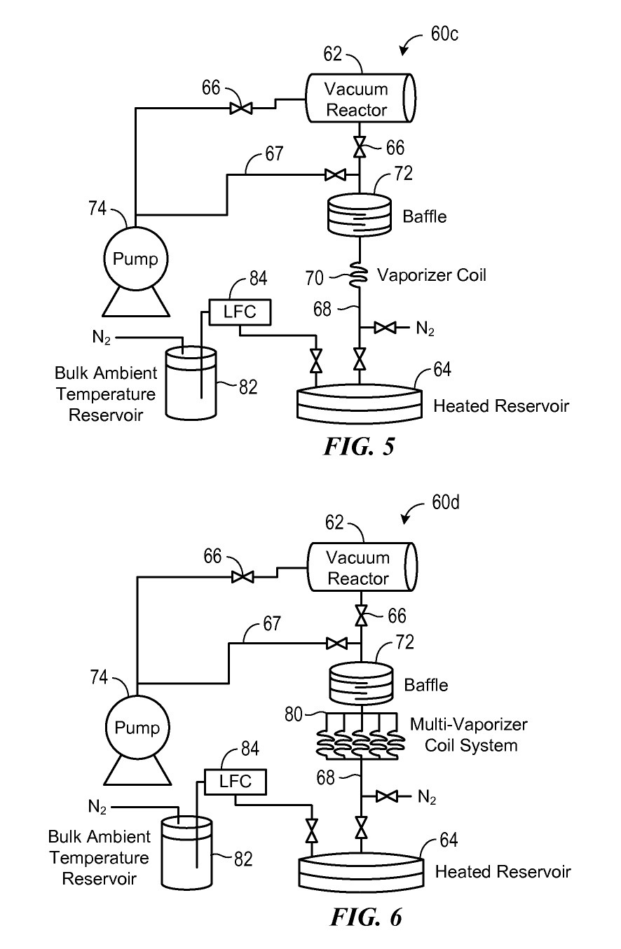

FIGS. 5 and 6 illustrate vapor delivery systems 60c and 60d that may be used wherein the bulk storage reservoir 82 (containing e.g., ValMat®) can be kept in the room temperature and precisely metered liquid ValMat® can be injected to the heated reservoir 64 which is heated at high temperatures for increased vapor pressure. As such, bulk ValMat® in reservoir 82 will have a long lifetime of twelve (12) months or more and systems 60c and 60d may not be limited by pressure of fluid at a reservoir temperature setpoint. Generally, then, two reservoir systems 64 and 82 may be used. Bulk storage reservoir 82 may be contained at ambient temperature for bulk liquid storage. Bulk storage reservoir 82 may then supply reservoir 64, which can be referred to as a fluid retention reservoir. Reservoir 64 may be kept at a high temperature (e.g., greater than approximately 90° C.) for point of use vaporization of fluid (e.g., ValMat®®). Fluid in liquid form may be transported from reservoir 82 using nitrogen backpressure and/or a liquid flow controller 84. Nitrogen backpressure and liquid flow controller 84 may provide prevision liquid injection to reservoir 64. Systems 60c and 60d may contain single vaporizer system 70 (shown in FIG. 5) or a multi-vaporizer system 80 (shown in FIG. 6). Single or multiple vaporizer systems 70 or 80 may be selected based on throughput requirements of the system supported.

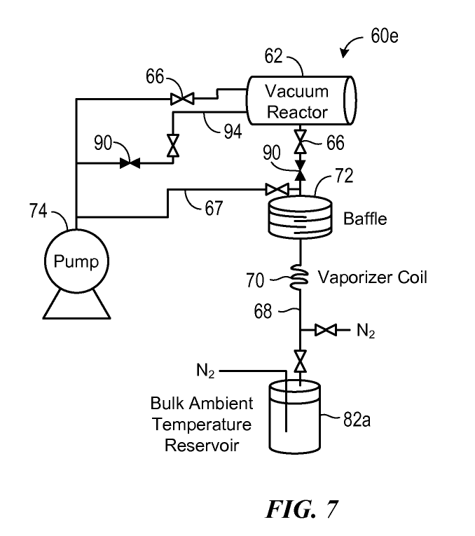

FIG. 7 illustrates another exemplary embodiment of vapor delivery system 60e. Vapor delivery system 60e includes reservoir 82a. Reservoir 82a may be kept at a constant temperature (e.g., room temperature). A gas line may be used to transport a carrier gas (e.g., N₂) to reservoir 82a. For example, during operation, N₂ gas may be passed through reservoir 82a toward vaporizer coil 70 and baffle 72 delivering fluid (e.g., ValMat®) to reactor 62. A second N₂ line may be used to prevent fluid from reacting when system 60e is idle.

For simplicity, vaporizer coil 70 and baffle 72 may be removed from system 60e. Additionally, a particle filter may be used to provide cleanliness during use of system 60e.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description. Changes may be made in the elements described herein without departing from the spirit and scope as described in the following claims.

What is claimed is:

1. A vapor delivery system for delivering a vaporized adhesive material to a substrate for use in an imprint lithography process, the system comprising:
a reactor chamber configured to retain one or more substrates, the reactor chamber in fluid communication with a vacuum source and further including one or more inlets;
a fluid retention reservoir configured to retain liquid adhesive material;
a delivery line connecting the fluid retention reservoir to the one or more inlets of the reaction chamber; and
an inline vaporizer positioned along the delivery line, the inline vaporizer further comprising one or more small diameter coiled tubes.

2. The vapor delivery system of claim 1 further comprising a baffle positioned along the delivery line between the vaporizer and the reactor chamber.

3. The vapor delivery system of claim 1 further comprising one or more purge valves located along the delivery line.

4. The vapor delivery system of claim 1 further comprising a N₂ purge line connected to the delivery line between the fluid retention reservoir and the vaporizer.

5. The vapor delivery system of claim 1 further comprising a vacuum bypass line connected to the delivery line between the vaporizer and the reactor.

6. The vapor delivery system of claim 1 further comprising a heating element for heating any one or more of the fluid retention reservoir, vaporizer and reactor.

7. The vapor delivery system of claim 1 further comprising multiple inline vaporizers.

8. The vapor delivery system of claim 1 further comprising a bulk storage reservoir in fluid communication with the retention reservoir.

9. The vapor delivery system of claim 8 further comprising a flow controller located between the bulk storage reservoir and the retention reservoir for controlling flow of liquid adhesive material from the bulk storage reservoir to the retention reservoir.

10. A vapor delivery system for delivering a vaporized adhesive material to a substrate for use in an imprint lithography process, the system comprising:
a reactor chamber configured to retain one or more substrates, the reactor chamber in fluid communication with a vacuum source and further including one or more inlets;
a fluid retention reservoir configured to retain liquid adhesive material;
a bulk storage reservoir in fluid communication with the fluid retention reservoir;
a flow controller located between the bulk storage reservoir and the retention reservoir for controlling flow of liquid adhesive material from the bulk storage reservoir to the retention reservoir
a delivery line connecting the fluid retention reservoir to the one or more inlets of the reaction chamber;
an inline vaporizer positioned along the delivery line, the inline vaporizer further comprising one or more small diameter coiled tubes; and
a baffle positioned along the delivery line between the vaporizer and the reactor chamber.

11. The vapor delivery system of claim 10 further comprising a N₂ purge line connected to the delivery line between the fluid retention reservoir and the vaporizer.

12. The vapor delivery system of claim 10 further comprising a vacuum bypass line connected to the delivery line between the vaporizer and the reactor.

13. The vapor delivery system of claim 10 further comprising multiple inline vaporizers.

14. A method for delivering a vaporized adhesive material to a substrate for use in an imprint lithography process, the method comprising:
providing adhesive material in liquid form to a reservoir;
heating the reservoir to produce gaseous adhesive material;
directing the gaseous adhesive material through one or more small diameter coiled tubes to produce vaporized adhesive material;
directing the vaporized adhesive material to a reactor chamber, the reactor chamber containing one or more substrates;
allowing the vaporized adhesive material to deposit on the one or more substrates.

15. The vapor delivery method of claim 14 further comprising directing the vaporized adhesive material through a baffle prior to directing the vaporized adhesive material to the reactor chamber.

16. The vapor delivery method of claim 14 further comprising restricting the flowrate of the vaporized adhesive material to increase vaporization efficiency.

17. The vapor delivery method of claim 14 further comprising directing the vaporized adhesive material through multiple small diameter coiled tubes.

18. The vapor delivery method of claim 14 further comprising subjecting the vaporized adhesive material to a vacuum.

19. The vapor delivery method of claim 14 further comprising providing a bulk storage reservoir in fluid communication with the reservoir to provide the liquid adhesive material to the reservoir.

20. The vapor delivery method of claim 18 wherein the bulk storage reservoir is kept at ambient temperature.

21. The vapor delivery method of claim 14 further comprising heating any one or more of the fluid retention reservoir, vaporizer and reactor.

22. The vapor delivery method of claim 14 wherein the adhesive material further comprises a silane compound having a functional group capable of covalently bonding to a polymerizable material typically used in an imprint lithography process, a —CH₂— linker group, and an Si atom having hydrolizable leaving groups.

23. The vapor delivery method of claim 14 wherein the adhesive material further comprises acryloxymethyltrimethoxysilane.
